(19) United States
(12) Patent Application Publication
(10) Pub. No.: US 2026/0076100 A1
(43) Pub. Date: Mar. 12, 2026

(54) SYSTEMS AND METHODS FOR A DYNAMICALLY TUNABLE STRAIN QUANTUM SENSOR BASED ON h-BN

(71) Applicant: Toyota Motor Engineering & Manufacturing North America, Inc., Plano, TX (US)

(72) Inventors: Naveed HUSSAIN, Ypsilanti, MI (US); Songtao WU, Ann Arbor, MI (US); Shuogo HIGASHI, Ann Arbor, MI (US); Debasish BANERJEE, Ypsilanti, MI (US)

(73) Assignees: Toyota Motor Engineering & Manufacturing North America, Inc., Plano, TX (US); Toyota Jidosha Kabushiki Kaisha, Toyota-shi, Aichi-ken (JP)

(21) Appl. No.: 18/827,488

(22) Filed: Sep. 6, 2024

(51) Int. Cl. H10N 50/85; G01R 33/00; G02B 6/122; H10N 50/01

(52) U.S. Cl. CPC H10N 50/85; G01R 33/0052; G02B 6/1226; H10N 50/01

(57) ABSTRACT

A method and computer program product for fabricating a quantum sensor, and a quantum sensor. The quantum sensor may be fabricated, wherein the quantum sensor includes a piezoelectric substrate. The quantum sensor may further include a plasmonic waveguide above the piezoelectric substrate. The quantum sensor may further include a 2D-material layer above the plasmonic waveguide. The quantum sensor may further include one or more electrical contacts below the piezoelectric substrate.

### BACKGROUND

Hexagonal Boron Nitride (h-BN) is an example 2D-material that may host spin-active boron vacancy

$$( {V}_{B}^{-} )$$

defects may be utilized as, e.g., quantum magnetometers via optical detection of magnetic resonance (ODMR). Generally, for the device to function properly, optical excitation may be performed in conjunction with microwave excitation, which may be used to create transitions in the quantum energy levels of the

$${V}_{B}^{-}$$

defects.

### BRIEF SUMMARY OF DISCLOSURE

In one example implementation, a method may include but is not limited to fabricating a quantum sensor. The quantum sensor may include a piezoelectric substrate. The quantum sensor may further include a plasmonic waveguide above the piezoelectric substrate. The quantum sensor may further include a 2D-material layer above the plasmonic waveguide. The quantum sensor may further include one or more electrical contacts below the piezoelectric substrate.

One or more of the following example features may be included. The piezoelectric substrate may include aluminum nitride. The plasmonic waveguide may include gold. The 2D-material layer may include hexagonal boron nitride (h-BN). The h-BN may host quantum boron vacancy

$$( {V}_{B}^{-} )$$

defects. The one or more electrical contacts may be configured to connect to an external electrical biasing circuit. An electrical bias applied to the one or more electrical contacts by the external electrical biasing circuit may induce a controllable strain within the piezoelectric substrate.

In another example implementation, a computer program product may reside on a computer readable storage medium having a plurality of instructions stored thereon which, when executed across one or more processors, may cause at least a portion of the one or more processors to perform operations that may include but are not limited to fabricating a quantum sensor. The quantum sensor may include a piezoelectric substrate. The quantum sensor may further include a plasmonic waveguide above the piezoelectric substrate. The quantum sensor may further include a 2D-material layer above the plasmonic waveguide. The quantum sensor may further include one or more electrical contacts below the piezoelectric substrate.

One or more of the following example features may be included. The piezoelectric substrate may include aluminum nitride. The plasmonic waveguide may include gold. The 2D-material layer may include hexagonal boron nitride (h-BN). The h-BN may host quantum boron vacancy

$$( {V}_{B}^{-} )$$

defects. The one or more electrical contacts may be configured to connect to an external electrical biasing circuit. An electrical bias applied to the one or more electrical contacts by the external electrical biasing circuit may induce a controllable strain within the piezoelectric substrate.

In another example implementation, a quantum sensor may include but is not limited to a piezoelectric substrate. The quantum sensor may further include a plasmonic waveguide above the piezoelectric substrate. The quantum sensor may further include a 2D-material layer above the plasmonic waveguide. The quantum sensor may further include one or more electrical contacts below the piezoelectric substrate.

One or more of the following example features may be included. The piezoelectric substrate may include aluminum nitride. The plasmonic waveguide may include gold. The 2D-material layer may include hexagonal boron nitride (h-BN). The h-BN may host quantum boron vacancy

$$( {V}_{B}^{-} )$$

defects. The one or more electrical contacts may be configured to connect to an external electrical biasing circuit. An electrical bias applied to the one or more electrical contacts by the external electrical biasing circuit may induce a controllable strain within the piezoelectric substrate.

The details of one or more example implementations are set forth in the accompanying drawings and the description below. Other possible example features and/or possible example advantages will become apparent from the description, the drawings, and the claims. Some implementations may not have those possible example features and/or possible example advantages, and such possible example features and/or possible example advantages may not necessarily be required of some implementations.

### BRIEF DESCRIPTION OF THE DRAWINGS

FIG. 1 is an example diagrammatic view of a dynamically tunable strain sensor according to one or more example implementations of the disclosure;

FIG. 2 is an example diagrammatic view of a dynamically tunable strain sensor with voltage and without voltage according to one or more example implementations of the disclosure;

FIG. 3 is an example flowchart of a fabrication process according to one or more example implementations of the disclosure.

Like reference symbols in the various drawings may indicate like elements.

### DETAILED DESCRIPTION

### System Overview:

Hexagonal Boron Nitride (h-BN) is an example 2D-material that may host quantum boron vacancy

$$( {V}_{B}^{-} )$$

defects. These defects may be utilized as quantum magnetometers via, e.g., optical detection of magnetic resonance (ODMR). Generally, for the device to function properly, optical excitation may be performed in conjunction with microwave excitation, and microwave excitation may be used to create transitions in the quantum levels of the

$${V}_{B}^{-}$$

defects. Current h-BN strain sensors, despite their impressive sensitivity, hold a critical limitation they lack the ability to adjust for strain caused by movement. This is because they rely on static features, like plane gold or nanopillars, to incorporate plasmonic enhancement in light-matter interaction. The problem arises when the sensor itself or the target object experiences movement. This movement introduces strain, which disrupts the delicate interaction between light and the sensor's key elements

$${V}_{B}^{-}$$

defects. The disruption leads to inaccurate or fluctuating readings, rendering the sensor ineffective in real-world scenarios. Our invention directly addresses this problem by introducing a dynamically tunable h-BN strain sensor. This innovative design solves the limitation of static features by incorporating a substrate (e.g., a piezoelectric substrate). This allows for real-time adjustments to the sensor's sensitivity through electrical biasing. In essence, the sensor actively controls how light interacts with the

$${V}_{B}^{-}$$

defects, enabling it to adapt to dynamic strain conditions and providing accurate readings even when movement is involved. This breakthrough paves the way for h-BN sensors with significantly broader applicability in various fields.

Thus, as will be discussed in greater detail below, the present disclosure targets a new generation of dynamically tunable strain sensors based on h-BN with implanted

$${V}_{B}^{-}$$

defects. The above-noted current h-BN sensors, while sensitive, lack the ability to adjust for strain caused by lateral or elative movement, which limits their practicality in real-world applications. The present disclosure addresses this issue by introducing a dynamically tunable sensor utilizing a substrate (e.g., a piezoelectric substrate), which thus allows for real-time adjustments to the sensor's sensitivity through electrical biasing, making it ideal for diverse applications like monitoring strain in muscle or machine relevant motion during exercise or tracking variations in structures under dynamic loads.

In some implementations, the present disclosure may be embodied as a method, system, or computer program product, e.g., via a fabrication process, such as fabrication process 10. Accordingly, in some implementations, the present disclosure (e.g., via fabrication process 10) may take the form of an entirely hardware implementation, an entirely software implementation (including firmware, resident software, micro-code, etc.) or an implementation combining software and hardware aspects that may all generally be referred to herein as a “circuit,” “module” or “system.” Furthermore, in some implementations, the present disclosure (e.g., via fabrication process 10) may take the form of a computer program product on a computer-usable storage medium having computer-usable program code embodied in the medium. Furthermore, in some implementations, the present disclosure (e.g., via fabrication process 10) may take the form of human actions, or a combination of human, hardware/software, computer program product actions. In some implementations, the hardware/software, computer program product actions may be executed on equipment commonly used in the semiconductor industry. For example, regarding simulation of the RF (radio frequency) characteristics, a variety of RF simulation software may be used, including but not limited to COMSOL, MATlab, Altium etc. Designing of the device may be done in a variety of computer aided design (CAD) software, such as AutoCAD, solidworks, etc. For fabrication, various equipment may be involved. Some of the more important ones being physical vapor deposition systems (e.g., magnetron sputtering, e-beam evaporation, etc. to deposit the metallic or insulating layers and for ion etching), spin coaters for coating of resist layers, laser writers and UV (ultraviolet) lithography machines for the lithography steps, scanning electron microscopes/optical microscopes for imaging and characterization, etc.

In some implementations, any suitable computer usable or computer readable medium (or media) may be utilized. The computer readable medium may be a computer readable signal medium or a computer readable storage medium. The computer-usable, or computer-readable, storage medium (including a storage device associated with a computing device or client electronic device) may be, for example, but is not limited to, an electronic, magnetic, optical, electromagnetic, infrared, or semiconductor system, apparatus, device, or any suitable combination of the foregoing. More specific examples (a non-exhaustive list) of the computer-readable medium may include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a digital versatile disk (DVD), a static random access memory (SRAM), a memory stick, a floppy disk, a mechanically encoded device such as punch-cards or raised structures in a groove having instructions recorded thereon, a media such as those supporting the internet or an intranet, or a magnetic storage device. Note that the computer-usable or computer-readable medium could even be a suitable medium upon which the program is stored, scanned, compiled, interpreted, or otherwise processed in a suitable manner, if necessary, and then stored in a computer memory. In the context of the present disclosure, a computer-usable or computer-readable, storage medium may be any tangible medium that can contain or store a program for use by or in connection with the instruction execution system, apparatus, or device.

In some implementations, a computer readable signal medium may include a propagated data signal with computer readable program code embodied therein, for example, in baseband or as part of a carrier wave. In some implementations, such a propagated signal may take any of a variety of forms, including, but not limited to, electro-magnetic, optical, or any suitable combination thereof. In some implementations, the computer readable program code may be transmitted using any appropriate medium, including but not limited to the internet, wireline, optical fiber cable, RF, etc. In some implementations, a computer readable signal medium may be any computer readable medium that is not a computer readable storage medium and that can communicate, propagate, or transport a program for use by or in connection with an instruction execution system, apparatus, or device.

In some implementations, computer program code for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Java®, Smalltalk, C++ or the like. Java® and all Java-based trademarks and logos are trademarks or registered trademarks of Oracle and/or its affiliates. However, the computer program code for carrying out operations of the present disclosure may also be written in conventional procedural programming languages, such as the “C” programming language, PASCAL, or similar programming languages, as well as in scripting languages such as Javascript, PERL, or Python. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through a local area network (LAN), a wide area network (WAN), a body area network BAN), a personal area network (PAN), a metropolitan area network (MAN), etc., or the connection may be made to an external computer (for example, through the internet using an Internet Service Provider). In some implementations, electronic circuitry including, for example, programmable logic circuitry, an application specific integrated circuit (ASIC), field-programmable gate arrays (FPGAs) or other hardware accelerators, micro-controller units (MCUs), or programmable logic arrays (PLAs) may execute the computer readable program instructions/code by utilizing state information of the computer readable program instructions to personalize the electronic circuitry, in order to perform aspects of the present disclosure.

In some implementations, the flowchart and block diagrams in the figures illustrate the architecture, functionality, and operation of possible implementations of apparatus (e.g., systems), methods and computer program products according to various implementations of the present disclosure. Each block in the flowchart and/or block diagrams, and combinations of blocks in the flowchart and/or block diagrams, may represent a human action, module, segment, or portion of code, which comprises one or more executable computer program instructions for implementing the specified logical function(s)/act(s). These computer program instructions may be provided to a processor of a general purpose computer, special purpose computer, or other programmable data processing apparatus to produce a machine, such that the computer program instructions, which may execute via the processor of the computer or other programmable data processing apparatus, create the ability to implement one or more of the functions/acts specified in the flowchart and/or block diagram block or blocks or combinations thereof. It should be noted that, in some implementations, the functions noted in the block(s) may occur out of the order noted in the figures (or combined or omitted). For example, two blocks shown in succession may, in fact, be executed substantially concurrently, or the blocks may sometimes be executed in the reverse order, depending upon the functionality involved.

In some implementations, these computer program instructions may also be stored in a computer-readable memory that can direct a computer or other programmable data processing apparatus to function in a particular manner, such that the instructions stored in the computer-readable memory produce an article of manufacture including instruction means which implement the function/act specified in the flowchart and/or block diagram block or blocks or combinations thereof.

In some implementations, the computer program instructions may also be loaded onto a computer or other programmable data processing apparatus to cause a series of operational steps to be performed (not necessarily in a particular order) on the computer or other programmable apparatus to produce a computer implemented process such that the instructions which execute on the computer or other programmable apparatus provide steps for implementing the functions/acts (not necessarily in a particular order) specified in the flowchart and/or block diagram block or blocks or combinations thereof.

### Dynamically Tunable 2D-Material-Based Quantum Sensor:

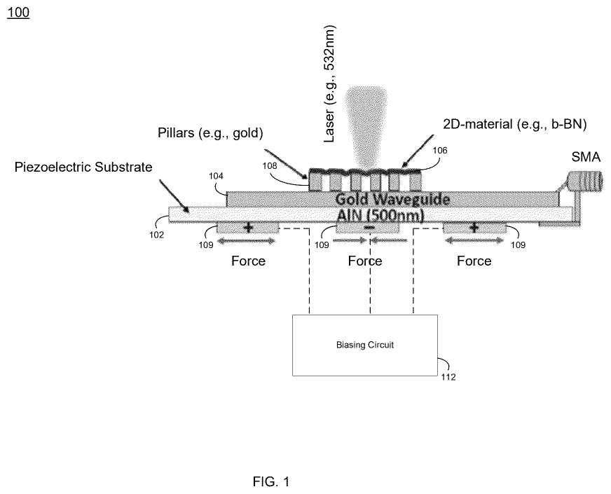

As discussed above and referring also at least to the example implementations of FIGS. 1-3, a fabrication process, such as fabrication process 110, may fabricate 300 a quantum sensor. The quantum sensor may include a piezoelectric substrate. The quantum sensor may further include a plasmonic waveguide above the piezoelectric substrate. The quantum sensor may further include a 2D-material layer above the plasmonic waveguide. The quantum sensor may further include one or more electrical contacts below the piezoelectric substrate.

As noted above, current h-BN strain sensors, despite their impressive sensitivity, hold a critical limitation (e.g., they lack the ability to adjust for strain caused by movement). This is because they rely on static features, like plane gold or nanopillars, to incorporate plasmonic enhancement in light-matter interaction. These features cannot adapt to dynamic strain, disrupting the interaction between light and the sensor's core element boron vacancy defects. This disruption leads to fluctuating or inaccurate readings. The problem arises when the sensor itself or the target object experiences relative movement. This movement introduces strain, which disrupts the delicate interaction between light and defects. This disruption leads to inaccurate or fluctuating readings, rendering the sensor ineffective in real-world scenarios. Thus, the present disclosure directly addresses this example and non-limiting problem by introducing a dynamically tunable h-BN strain quantum sensor. This innovative design solves the limitation of static features by incorporating a substrate (e.g., a piezoelectric substrate such as aluminum nitride). This allows for real-time adjustments to the sensor's sensitivity through electrical biasing. In essence, the sensor actively controls how light interacts with the boron vacancy defects, enabling it to adapt to dynamic strain conditions and providing accurate readings even when movement is involved. This breakthrough paves the way for h-BN sensors with significantly broader applicability in various fields. By applying an electrical bias, the sensor's sensitivity can be adjusted in real-time, making it suitable for various strain sensing applications involving movement. While the core functionality revolves around dynamic strain sensing, it will be appreciated after reading the present disclosure that the sensor holds the potential to be a multipurpose quantum sensor capable of simultaneous strain and electrical sensing.

In some implementations, fabrication process 10 may fabricate 300 a quantum sensor. For instance, and referring at least to the example implementation of FIG. 1, a dynamically tunable strain sensor (e.g., quantum sensor 100) is shown. In the example, quantum sensor 100 is shown with a substrate (e.g., piezoelectric substrate 102), a plasmonic waveguide (e.g., plasmonic waveguide 104) above piezoelectric substrate 102, a 2D-material layer (e.g., 2D-material layer 106) above plasmonic waveguide 104 on pillars (e.g., pillars 108 above plasmonic waveguide 104), and one or more electrical contacts (e.g., electrical contacts 109) below piezoelectric substrate 102.

In some implementations, piezoelectric substrate 102 may include aluminum nitride (AIN) or other suitable substrate. This substrate may replace other types of substrates (e.g., sapphire) and may form the foundation of quantum sensor 100. Notably, as will be discussed in greater detail below, AIN exhibits the piezoelectric effect, where an applied voltage induces a precise strain within the material.

In some implementations, 2D-material layer 106 may include hexagonal boron nitride (h-BN), and in some implementations, the h-BN may host quantum boron vacancy

$$( {V}_{B}^{-} )$$

defects. For instance, as seen at least in FIG. 1, 2D-material layer 106 is shown as a thin layer of h-BN containing boron vacancy

$$( {V}_{B}^{-} )$$

defects that rest on top or pillars 108 fabricated on the AIN substrate. These defects interact with the light to provide strain information.

In some implementations, plasmonic waveguide 104 may include gold. In the example, plasmonic waveguide 104 may be a metallic waveguide (e.g., gold, silver, aluminum, etc.) fabricated on the AIN substrate (i.e., piezoelectric substrate 102). Plasmonic waveguide 104 concentrates and directs incoming light (e.g., via a laser) towards d-material layer 106, optimizing light-matter interaction with the

$${V}_{B}^{-}$$

defects.

In some implementations, electrical contacts 109 below piezoelectric substrate 102 may be made of a metal (e.g., gold/platinum, etc.). Electrical contacts 109 may be deposited on the bottom of piezoelectric substrate 102 by using, e.g., nanofabrication techniques and connect to an external electrical biasing circuit (e.g., electrical biasing circuit 112). In some implementations, all components are physically aligned in vertical stacking order on a PCB.

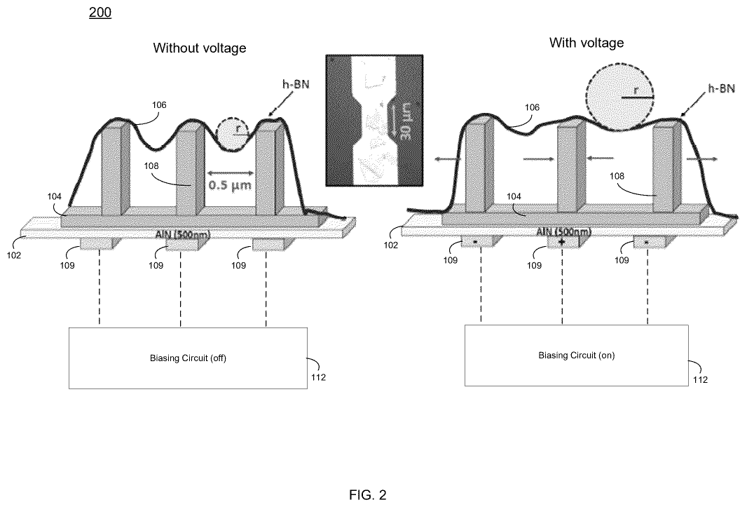

In some implementations, electrical contacts 109 may be configured to connect to an external electrical biasing circuit (e.g., electrical biasing circuit 112), where an electrical bias applied to the electrical contacts 109 by electrical biasing circuit 112, which may induce a controllable strain within piezoelectric substrate 102. For instance, and referring at least to the example implementation of FIG. 2, an example diagrammatic view 200 of the dynamically tunable strain sensor of FIG. 1 is shown with voltage and without voltage being applied. As can be seen, when electrical biasing circuit 112 is off, and thus no voltage is being applied (shown on the left of FIG. 2), the radius between pillars 108 is smaller than when electrical biasing circuit 112 is on, and thus providing voltage (shown on the right of FIG. 2). In the example, the radius is 0.5 um; however, it will be appreciated that the radius will vary depending upon the characteristics of quantum sensor 100 and/or the amount of voltage applied. Similarly, the length of 30 um shown in FIG. 2 should also be taken as example only and may change depending upon desired characteristics.

Using AIN (e.g., 500 nm) as the substrate material allows for precise control of the sensor's sensitivity through the above-noted applied electrical bias. For instance, AIN has the in-plane piezoelectric coefficient d₃₁ and out-of-plane d₃₃ of −2.0 pm/V and 3.9 pm/V, respectively. The strain along the in-plane or out-plane direction can be calculated using the following equation:

$$S = {d}_{31} E$$

Where S is the mathematical strain produced by the reverse piezoelectric effect, d₃₁ is the in-plane piezoelectric coefficient of AIN, and E is the magnitude of the applied electric field. The piezoelectric effect translates this bias into a controllable two-way tensile strain within the substrate. This controlled strain effectively tunes the light-matter interaction with the

$${V}_{B}^{-}$$

defects, enabling the sensor to adapt to dynamic strain conditions and deliver accurate readings even during movement.

The use of well-established fabrication techniques for AIN substrates and electrical contacts ensures the potential for mass production, making this technology readily available for various applications. The example design maintains a simple device architecture. The core components h-BN layer, plasmonic waveguide, and electrical contacts are integrated on the AIN substrate. This simplifies fabrication and facilitates future integration with existing sensor platforms. In essence, the present disclosure describes a dynamically tunable, scalable, and easy-to-manufacture h-BN strain sensor, paving the way for a new generation of highly adaptable and versatile strain sensing devices.

The breakdown of the key operational setups is provided below:
Light Excitation: External light interacts with the plasmonic waveguide, concentrating it and directing it towards the h-BN layer.

$${V}_{B}^{-}$$

defects Light-Matter Interaction: The concentrated light interacts with the in the h-BN, affecting their spin state.
Dynamic Strain Control: An electrical bias is applied to the contacts. This bias, due to the piezoelectric effect in AIN, induces a controllable strain within the substrate.
Tunable Sensitivity: This applied strain alters the interaction between light and the

$${V}_{B}^{-}$$

defects. By adjusting the electrical bias, we can effectively tune the sensor's sensitivity in real-time. The changes in photoluminescence (PL) and optically detected magnetic resonance (ODMR) curve (e.g., intensity, line shape, peak position, etc.) will provide the information about strain monitoring.

Light Emission and optical readout: Depending on the interaction between light and the

$${V}_{B}^{-}$$

defects under the applied strain, they may emit light at a specific wavelength. Sensitive photodetectors capture the emitted light from the

$${V}_{B}^{-}$$

defects.
Data Analysis: The captured light signal is analyzed to extract information about the applied strain.
Strain Estimation: To ensure accurate quantum sensing, it is suggested to estimate the strain applied to the h-BN. This can be achieved by, e.g., analyzing Field Emission Scanning Electron Microscope (FESEM) images. As shown in FIG. 2, the radius of curvature of h-BN draped over gold nanopillars, both with and without applied voltage, can be leveraged to calculate the strain on h-BN by using the example and non-limiting formula:

$$ε = {d}_{BN} / 2 R$$

Where d is the thickness of h-BN, while R is the radius of curvature (shown in FIG. 2).

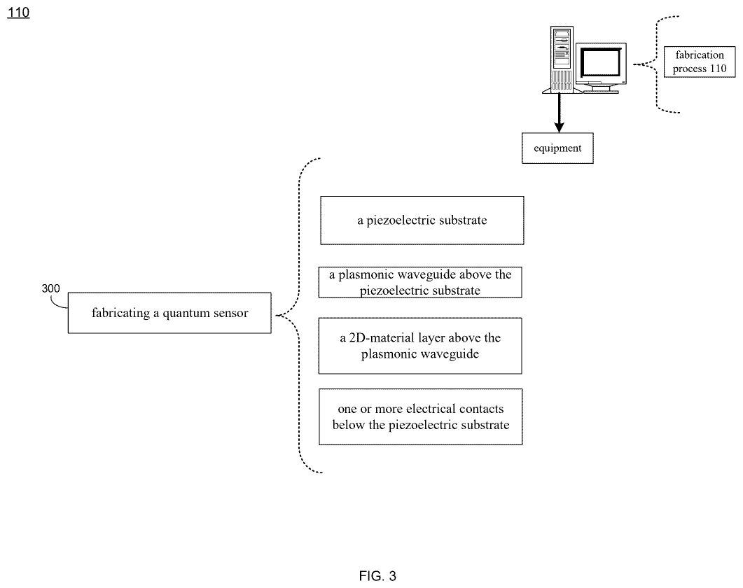

It will be appreciated after reading the present disclosure that any standard PCB assembly/printing/fabrication, etc. equipment, as well as any other necessary equipment, and any particular location, such as at a foundry, fabrication facility, etc. may be used singly or in any combination with fabrication process 110, which may be operatively connected to a computing device, such as the computing device shown in FIG. 3, to obtain their instructions for creating and/or executing one or more aspects of the present disclosure. In one or more example implementations, the respective flowcharts may be manually implemented, computer-implemented, or a combination thereof.

The terminology used herein is for the purpose of describing particular implementations only and is not intended to be limiting of the disclosure. As used herein, the singular forms “a”, “an” and “the” are intended to include the plural forms as well, unless the context clearly indicates otherwise. As used herein, the language “at least one of A and B” (and the like) as well as “at least one of A or B” (and the like) should be interpreted as covering only A, only B, or both A and B, unless the context clearly indicates otherwise. It will be further understood that the terms “comprises” and/or “comprising,” when used in this specification, specify the presence of stated features, integers, steps (not necessarily in a particular order), operations, elements, and/or components, but do not preclude the presence or addition of one or more other features, integers, steps (not necessarily in a particular order), operations, elements, components, and/or groups thereof.

The corresponding structures, materials, acts, and equivalents (e.g., of all means or step plus function elements) that may be in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications, variations, substitutions, and any combinations thereof will be apparent to those of ordinary skill in the art without departing from the scope and spirit of the disclosure. The implementation(s) were chosen and described in order to explain the principles of the disclosure and the practical application, and to enable others of ordinary skill in the art to understand the disclosure for various implementation(s) with various modifications and/or any combinations of implementation(s) as are suited to the particular use contemplated.

Having thus described the disclosure of the present application in detail and by reference to implementation(s) thereof, it will be apparent that modifications, variations, and any combinations of implementation(s) (including any modifications, variations, substitutions, and combinations thereof) are possible without departing from the scope of the disclosure defined in the appended claims.

What is claimed is:

1. A method comprising:
fabricating a quantum sensor, wherein the quantum sensor includes:
a piezoelectric substrate;
a plasmonic waveguide above the piezoelectric substrate;
a 2D-material layer above the plasmonic waveguide; and
one or more electrical contacts below the piezoelectric substrate.

2. The method of claim 1, wherein the piezoelectric substrate includes aluminum nitride.

3. The method of claim 1, wherein the plasmonic waveguide includes gold.

4. The method of claim 1, wherein the 2D-material layer includes hexagonal boron nitride (h-BN).

5. The method of claim 4, wherein the h-BN hosts quantum boron vacancy
$$( {V}_{B}^{-} )$$
defects.

6. The method of claim 1, wherein the one or more electrical contacts are configured to connect to an external electrical biasing circuit.

7. The method of claim 6, wherein an electrical bias applied to the one or more electrical contacts by the external electrical biasing circuit induces a controllable strain within the piezoelectric substrate.

8. A computer program product residing on a computer readable storage medium having a plurality of instructions stored thereon which, when executed across one or more processors, causes at least a portion of the one or more processors to perform operations comprising:
fabricating a quantum sensor, wherein the quantum sensor includes:
a piezoelectric substrate;
a plasmonic waveguide above the piezoelectric substrate;
a 2D-material layer above the plasmonic waveguide; and
one or more electrical contacts below the piezoelectric substrate.

9. The computer program product of claim 8, wherein the piezoelectric substrate includes aluminum nitride.

10. The computer program product of claim 8, wherein the plasmonic waveguide includes gold.

11. The computer program product of claim 8, wherein the 2D-material layer includes hexagonal boron nitride (h-BN).

12. The computer program product of claim 11, wherein the h-BN hosts quantum boron vacancy
$$( {V}_{B}^{-} )$$
defects.

13. The computer program product of claim 8, wherein the one or more electrical contacts are configured to connect to an external electrical biasing circuit.

14. The computer program product of claim 13, wherein an electrical bias applied to the one or more electrical contacts by the external electrical biasing circuit induces a controllable strain within the piezoelectric substrate.

15. A quantum sensor comprising:
a quantum sensor, wherein the quantum sensor includes:
a piezoelectric substrate;
a plasmonic waveguide above the piezoelectric substrate;
a 2D-material layer above the plasmonic waveguide; and
one or more electrical contacts below the piezoelectric substrate.

16. The quantum sensor of claim 15, wherein the piezoelectric substrate includes aluminum nitride.

17. The quantum sensor of claim 15, wherein the plasmonic waveguide includes gold.

18. The quantum sensor of claim 15, wherein the 2D-material layer includes hexagonal boron nitride (h-BN) hosting quantum boron vacancy
$$( {V}_{B}^{-} )$$
defects.

19. The quantum sensor of claim 15, wherein the one or more electrical contacts are configured to connect to an external electrical biasing circuit.

20. The quantum sensor of claim 19, wherein an electrical bias applied to the one or more electrical contacts by the external electrical biasing circuit induces a controllable strain within the piezoelectric substrate.
